(19) United States
(12) Patent Application Publication
(10) Pub. No.: US 2008/0139003 A1
(43) Pub. Date: Jun. 12, 2008

(54) BARRIER COATING DEPOSITION FOR THIN FILM DEVICES USING PLASMA ENHANCED CHEMICAL VAPOR DEPOSITION PROCESS

(76) Inventors: SHAHID PIRZADA, FREMONT, CA (US); MARVIN KESHNER, SONORA, CA (US); PAUL MCCLELLAND, MONMOUTH, OR (US); ERIK VAALER, REDWOOD CITY, CA (US)

Correspondence Address: WEISS & MOY PC, 4204 NORTH BROWN AVENUE, SCOTTSDALE, AZ, 85251, US

(21) Appl. No.: 11/960,844

(22) Filed: Dec. 20, 2007

Related U.S. Application Data
(63) Continuation-in-part of application No. 11/553,334, filed on Oct. 26, 2006.

(51) Int. Cl. H01L 21/469

(52) U.S. Cl. 438/785; 257/E21.487

(57) ABSTRACT

A method to produce barrier coatings (such as nitrides, oxides, carbides) for large area thin film devices such as solar panels or the like using a high frequency plasma enhanced chemical vapor deposition (PECVD) process is presented. The proposed process provides a uniform deposition of barrier coating(s) such as silicon nitride, silicon oxide, silicon carbide (SiNₓ, SiO₂, SiC) at a high deposition rate on thin film devices such as silicon based thin film devices at low temperature. The proposed process deposits uniform barrier coatings (nitrides, oxides, carbides) on large area substrates (about 1 m×0.5 m and larger) at a high frequency (27-81 MHz). Stable plasma maintained over a large area substrate at high frequencies allows high ionization density resulting in high reaction rates at lower temperature.

### CROSS-REFERENCE TO RELATED APPLICATIONS

The present application is a continuation-in-part of U.S. patent application entitled “PLASMA ENHANCED CHEMICAL VAPOR DEPOSITION APPARATUS AND METHOD”, Ser. No. 11/553,334 filed Oct. 26, 2006 and having at least one common inventor and assigned to the same assignee which claims priority to PCT/US2004/030275, herein incorporated by reference. This application is also related to application Ser. No. 11/420,429, filed May 25, 2006 and to U.S. Pat. No. 7,264,849 issued Sep. 4, 2007 both entitled “Roll-Vortex Plasma Chemical Vapor Deposition System” by at least one common inventor and assigned to the same assignee and herein incorporated herein by reference.

### BACKGROUND OF THE INVENTION

This invention relates generally to a method for producing barrier coatings using a high frequency plasma enhanced chemical vapor deposition (PECVD) process. More specifically, this invention relates to barrier coating deposition on large area thin film devices such as silicon photovoltaic cells.

PECVD is a well known technology in various industries (such as semiconductor, data storage, photovoltaic, flat panel display, and packaging) for thin film deposition on a variety of materials. Plasma is an ionized form of gas that can be obtained by ionizing a gas or liquid medium using an AC or DC electric field. Typically in a PECVD process, reactant precursors are excited and dissociated in the reaction zone by applying radio frequency energy to the reactants. The reactive species react at a substrate surface for the completion of the reaction. Highly reactive species involved in the chemical reaction scheme at the substrate allow lower temperatures for the completion of the reaction at high reaction rates. Reaction rates are enhanced by increasing the degree of ionization in the plasma chamber. High frequencies (27-81 MHz) form plasma with higher ionization density leading to high deposition rate with lower hydrogen content in the deposited film thereby decreasing the need for high temperature of the substrates. Keeping the substrate temperature low is a must for some applications where high temperatures can degrade the performance of the materials already deposited on the substrate

As described in U.S. Pat. No. 7,264,849 issued Sep. 4, 2007, entitled “Roll-Vortex Plasma Chemical Vapor Deposition System,” and Plasma Enhanced Chemical Vapor Deposition Apparatus and Method, application Ser. No. 11/553,334 filed Oct. 26, 2006, co-owned and incorporated herein by reference, the PECVD process is capable of producing high quality amorphous silicon thin film devices for the photovoltaic industry at a high deposition rate. This patent and patent application describe incorporating several tubular electrodes in the deposition chamber, operated at high frequency 27-81 MHz to provide a uniform deposition of high quality amorphous silicon film at a high deposition rate on a large size solar panel.

For such large area thin film solar panels, there is a need to protect the solar panels from moisture, oxygen, environmental pollutants, and other impurities. In the semiconductor industry, the use of barrier coatings to seal and protect solar panels is often referred to as “passivation”. For example, Si₃N₄ is a commonly used barrier coating and is often referred to as a “passivation layer” or “passivation film.” A barrier coating may be a single passivation layer or a stack of multiple passivation layers with identical or different compositions. The protective barrier coating for a solar cell or panel, for example, must be insulating with high dielectric strength, pore free, continuous, and conformal, covering various step heights on the panel.

PECVD processes have been used to produce barrier coatings for different applications. Examples of PECVD systems to deposit barrier coatings (such as silicon nitride) are described in U.S. Pat. Nos. 6,924,241; 5,418,019; 4,253,881; 6,150,286; 6,664,202; 6,756,324; 6,720,249; 6,984,893; 6,686,232; 4,563,367. For example, U.S. Pat. No. 6,924,241 describes a PECVD process operating at 13.56 MHz to produce an ultraviolet light (UV) transmissive silicon nitride layer. The process reduces the concentration of Si—H bonds in the silicon nitride film to provide UV transmissivity. The film may be used as a passivation layer in a UV erasable memory integrated circuit. The reactor used in this patent is a CONCEPT ONE dual-frequency parallel plate PECVD reactor from Novellus Systems, Inc.

Another example is U.S. Pat. No. 6,664,202, where a mixed frequency PECVD process is utilized to create high quality silicon nitride layer having high conformality. In a mixed frequency PECVD process, both high and low frequency RF energy (e.g. one 13.56 MHz and one signal less than 1 MHz) is applied to one or more electrodes positioned near the reaction zone.

U.S. Pat. No. 5,418,019 describes a method for low temperature plasma enhanced chemical vapor deposition of SiN and SiO₂ antireflective coating on silicon. A PECVD reactor developed by Plasma-Therm (series 700) was used to deposit these films at 13.56 MHz RF power range. The substrate temperature was 300° C. in this deposition.

Silicon nitride is a good insulating material to be used as a barrier-coating passivation layer on the thin film solar cell. Silicon nitride (Si₃N₄) is known for its barrier properties to moisture, oxygen and environmental pollutants and is used as a barrier coating in semiconductor, data storage and packaging industries. Typically, silicon nitride is deposited either by reactive sputtering or by plasma enhanced chemical vapor deposition (PECVD) processes. Plasma enhanced chemical vapor deposition is a more attractive method than reactive sputtering due to its higher deposition rates and better conformality of the deposition. Typical silicon nitride deposition using PECVD is done at temperatures ˜300° C.

However, for passivation of silicon based thin film solar panels, the barrier coating must be applied at low temperature (<150° C.) to avoid degradation (at the p-i interface) of the semiconductor films already deposited on the substrate. Low temperatures, however, often lead to more particulate formation, which is undesirable.

There is therefore a need for a novel PECVD process for depositing barrier coatings on substrates with a high deposition rate (5 nm/sec), at low substrate temperature, and with less particulate formation over conventional PECVD processes. There is also a need for a novel PECVD process that has effective silane (SiH₄) utilization, deposition uniformity, and good for depositing barrier coatings on large area substrates (1 m×0.5 m and larger). The present invention fulfills these needs and provides other related advantages.

### BRIEF SUMMARY OF THE INVENTION

The primary objective of this invention is to produce barrier coatings, which passivation-layer compositions may include SiNₓ, SiO₂, SiC or the like for solar cell passivation using a high frequency (27-81 MHz) plasma enhanced chemical vapor deposition process. This PECVD process provides a substantially uniform deposition of barrier coatings at a high deposition rate on a large area thin film devices at low temperature (less than about 150 degrees Celsius, preferably about 100° C.).

### BRIEF DESCRIPTION OF THE DRAWINGS

FIG. 1 is a block diagram of a PECVD apparatus in accordance with an embodiment of a present invention.

FIG. 2 is a perspective, cutaway view of a deposition chamber in accordance with an embodiment of a present invention.

FIG. 3 is a section view taken along line 3-3 in FIG. 2.

FIG. 4 is a side view of rod electrodes in accordance with an embodiment of a present invention.

FIG. 5 is a simplified vertical cross sectional view of an exemplary barrier coating on an exemplary substrate in accordance with an embodiment of a present invention.

### DESCRIPTION OF THE INVENTION

### Description of the Specific Embodiments

The following is a detailed description of the best presently known modes of carrying out the inventions. This description is not to be taken in a limiting sense, but is made merely for the purpose of illustrating the general principles of the inventions. It should also be noted that detailed discussions of the various aspects of PECVD systems that are not pertinent to the present inventions have been omitted for the sake of simplicity.

“Barrier film(s)” and “barrier coating(s)” are used interchangeably herein to mean one or more inert passivation layers deposited on a substrate that stabilize the substrate, do not have an appreciable electrical effect on the substrate and substantially prevent moisture, oxygen, environmental pollutants, and other impurities or the like reaching the substrate.

“Substrate” as used herein means the object being coated by the process under discussion. Those skilled in the art understand that, at the beginning of a given process, a “substrate” may be uncoated, or it may already have one or more coatings deposited on its surface by previous processes.

The term “solar cells” as used herein includes a single photovoltaic element for converting sunlight to electricity.

The term “solar panels” as used herein means a large area device that includes a plurality of solar cells, interconnected in series and/or parallel, to create a power generating device with large voltage and current capability.

The term “silicon based thin-film devices” as used herein include amorphous, crystalline or partially crystalline silicon solar cells and panels and flat panel displays, and other electronic devices that include a thin layer of amorphous, crystalline or partially crystalline silicon as part of their structure.

The term “thin film device(s)” as used herein includes solar cells, solar panels and the terms “solar cells” and “solar panels” as used herein include “thin-film devices.” “Thin-film devices” also include window glass, flat panel displays, lenses, etc. and other large area substrates, silicon-based or not, that would benefit from a thin-film barrier coating. “Thin film device(s) as used herein may also include small area substrates that would benefit from a thin-film barrier coating such as wafer-based solar cells, optics or other semiconductor devices.

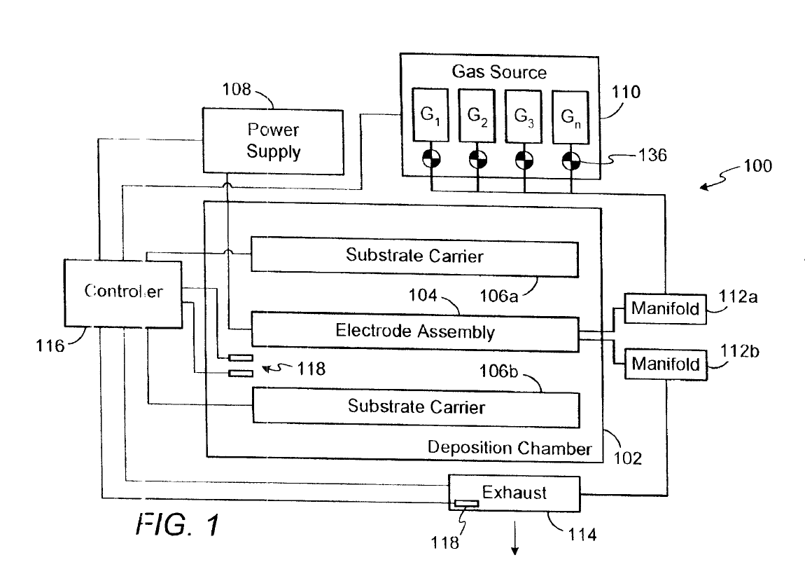

As illustrated for example in FIG. 1, a PECVD system 100 in accordance with one embodiment of a present invention includes a deposition chamber 102 with an electrode assembly 104 between a pair of substrate carriers 106a and 106b. The substrate carriers 106a and 106b position substrates on opposite sides of the electrode assembly 104. In a preferred embodiment, the substrates are silicon based thin film devices such as solar panels as hereinafter described. The electrode assembly 104 in the exemplary implementation performs a number of functions. The electrode assembly 104 creates one or more high intensity plasma regions between the substrate carriers 106a and 106b when excited by a voltage, e.g. radio frequency (RF) or direct current (DC), provided by a power supply 108. In one embodiment, alternate rod electrodes are excited with +RF and −RF so that the voltages on adjacent rod electrodes are out of phase with each other. This creates an intense plasma between the rod electrodes and a much weaker plasma out toward the substrates. The electrode assembly 104 also contains channels to deliver reactant gas to the deposition chamber 102 and is connected to a reactant gas source 110 by way of a manifold 112a. The gas is introduced into the chamber through apertures 134 in the rod electrodes. These apertures can be located on the surfaces closest to the substrates and away from the regions of intense plasma between the rod electrodes. In an alternate embodiment, they can be located on the surfaces that face the adjacent rod electrodes and inject the gas directly into the regions of intense plasma. During the deposition process, plasma is created in the area between substrates that are carried by the substrate carriers 106a and 106b and material from the reactant gas (e.g. silicon from silane and nitrogen from ammonia) SiNₓ is deposited from the plasma onto both of the substrates simultaneously to form films (e.g. silicon nitride films) on both of the substrates. In addition, the electrode assembly 104 is used to evacuate exhaust from the deposition chamber 102 and, to that end, is connected to an exhaust device 114, such as vacuum pump, by way of the manifold 112b. Operation of the PECVD system 100 is monitored and controlled by a controller 116, based at least in part on data from sensors 118.

Turning to FIGS. 2-4, the substrates 120a and 120b enter the exemplary deposition chamber 102 by way of inlets 122a and 122b and travel in the direction indicated by arrows A. Similar outlets (not shown) are provided at the opposite end of the deposition chamber 102. The substrates 120a and 120b may be in the form of individual sheets of underlying material coated with amorphous, crystalline or partially crystalline silicon P-I-N layers along with metal conductor layer that are each fed into the deposition chamber 102. The substrates may also be a continuous web of underlying material coated with amorphous, crystalline or partially crystalline silicon P-I-N along with metal conductor layers that is pulled from a supply roll to a take-up roll. Suitable underlying materials include, but are not limited to, soda-lime glass, polyimide, and stainless steel. Whether the underlying materials are in individual sheet or roll form, the substrate carriers 106a and 106b position the substrates 120a and 120b parallel to each other on opposite sides of the deposition chamber 102 and on opposite sides of the electrode assembly 104. The substrate carriers 106a and 106b also include a plurality of roller units 124 and the edges of the substrates 120a and 120b pass between the rollers in the associated roller units. The rollers in the roller units 124 may be free spinning rollers, which merely guide the substrates 120a and 120b through the deposition chamber 102 and ensure that they are properly positioned within the chamber. Alternatively, the roller units 124 may include driven rollers that drive the substrates 120a and 120b through the deposition chamber 102, in addition to ensuring that they are properly positioned. Other suitable substrate carriers include conveyor systems and chain drives. Alternatively, the substrates could be loaded into the chamber by a robot arm, held in place by sliding or roller guides and then removed from the chamber by the robot arm after the deposition is complete. Still another alternative is to employ rollers that engage the top and bottom edges of the substrates 120a and 120b and rotate about axes that are perpendicular to the direction indicated by arrows A.

The interior of the deposition chamber 102 in the exemplary embodiment is relatively narrow. More specifically, the distance between the substrates 120a and 120b is substantially less than the length of the chamber (measured in the direction of arrows A) and the height of the chamber (measured in the direction perpendicular to arrows A). For example, the distance between substrates 120a and 120b may be one-tenth or less of the length and height dimensions. The substrates 120a and 120b will also preferably extend from end to end in the length dimension of the deposition chamber 102 and from top to bottom in the height dimension. As a result, the substrates 120a and 120b will be between the electrode assembly 104 (and the plasma created thereby) and the large interior surfaces of the chamber and will substantially cover the vast majority of the interior surface of the deposition chamber 102.

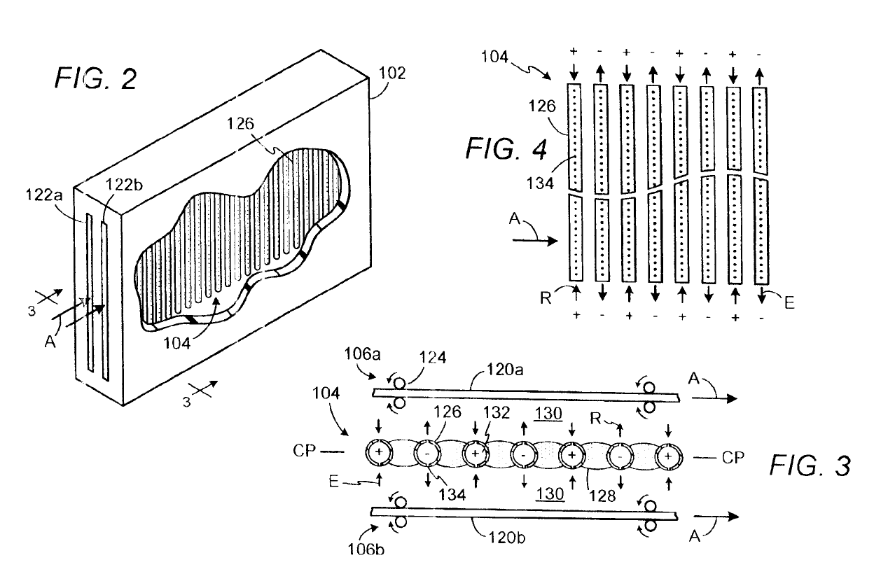

The deposition chamber 102 is not limited to any particular size. Nevertheless, in one exemplary implementation of the deposition chamber 102 that is suitable for commercial applications and is oriented in the manner illustrated in FIG. 2, the interior of the deposition chamber 102 is about 100 cm in length (measured in the direction of arrows A) and about 60 cm in height (measured in the direction perpendicular to arrows A). There is also about 7 cm between the substrates 120a and 120b and about 3.5 cm between the central plane CP of the deposition chamber interior (FIG. 3) and each of the substrates 120a and 120b. Additionally, the substrate carriers 106a and 106b are positioned and arranged such that the substrates 120a and 120b will lie in vertically extending planes. Such orientation reduces the likelihood that particulates will fall onto the substrates.

There are a number of advantages associated with deposition chambers that are configured in this manner. For example, the relatively small spacing between the substrates 120a and 120b, as compared to the relatively large dimension in the direction of substrate travel and the dimension perpendicular to substrate travel increases the percentage of the plasma generated silicon nitride that is deposited onto the substrates and decreases the amount that is deposited onto the chamber walls, as compared to conventional deposition chambers. As a result, the reactant materials are consumed more efficiently. The downtime and expense associated with deposition chamber cleaning and maintenance is also reduced. The close spacing between the electrode assembly 104 and the substrates 120a and 120b also facilitates rapid diffusion in the smallest dimension as the dominant process for transporting atomic nitrogen created at the center of the deposition chamber 102 to the substrates, where the atomic nitrogen can react with silane to deposit SiNₓ onto the substrates. The configuration of the deposition chamber 102 also allows rapid diffusion to equalize the concentrations of all species throughout the plasma, including the rapid diffusion of the input reactant gas, to obtain a uniform concentration.

The exemplary electrode assembly 104 illustrated in FIGS. 2-4 includes a plurality of spaced rod electrodes 126 arranged such that their respective longitudinal axes are co-planar, perpendicular to the direction of substrate travel (indicated by arrows A), and equidistant from the substrate carriers 106a and 106b (as well as substrates 120a and 120b). The rod electrodes 126 also extend from one end of the deposition chamber 102 to the other (top to bottom in the orientation illustrated in FIG. 2). The exemplary rod electrodes 126 are cylindrical in shape and are relatively close together. The spacing between adjacent rod electrodes 126 in the illustrated embodiment is about equal to the diameter of the rod electrodes (i.e. two times the diameter measured from longitudinal axis to longitudinal axis).

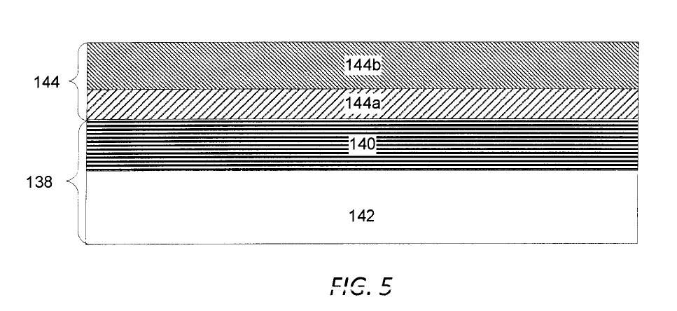

With respect to plasma formation, the electrode assembly 104 may be used to create high intensity plasma between the substrate carriers 106a and 106b (as well as substrates 120a and 120b). The high intensity plasma is created when the rod electrodes 126 are energized by power such as, for example, RF or DC power from the power supply 108. The energy is supplied in alternating phases from one rod electrode 126 to the next adjacent rod electrode, as is represented by the alternating series of “+” and “−” signs in FIGS. 3 and 4. The application of power in this manner creates regions of high intensity electric field between adjacent rod electrodes 126 and, accordingly, regions of intense plasma 128 between adjacent rod electrodes. Low intensity electric fields and low intensity plasma regions 130 are created near the substrates 120a and 120b. More specifically, in an exemplary implementation where adjacent rod electrodes 126 are spaced from one another by one rod diameter (i.e. two diameters from longitudinal axis to longitudinal axis) and the substrates spaced from the central plane CP by three and one-half rod electrode diameters, the intensity of the electric fields between the rod electrodes will be significantly greater than ten times the intensity of the electric field near the substrates 120a and 120b.

It should be noted that the rod electrodes 126 may, alternatively, be driven in phase with each other. Here, the substrates 120a and 120b are held at ground potential or at ground with a small DC bias. This will create a relatively uniform electric field and plasma in each of the two areas between the central plane CP and the substrates 120a and 120b.

If the deposition chamber and rod electrodes are short compared with a ¼ wavelength at the excitation frequency, then the rod electrodes 126 present a load having a capacitive reactance. The RF energy is coupled to the rod electrode in parallel with an inductive reactance so as to create a predominantly resonant circuit. However, the rod electrodes form a transmission line with a characteristic impedance similar to coaxial cables commonly used to transport RF energy from a RF power source to a load. As the length of the rod electrodes is increased and/or the RF frequency is increased, the length of the rod transmission line becomes comparable to ¼ wavelength of the RF frequency. In this case, the rod electrode is driven from each end with the appropriate value of inductance or capacitance to resonate it and effectively create a maximum voltage at the center of the rod electrode and a smaller voltage towards each end. In the embodiment of FIGS. 3 and 4, each rod electrode 126 is preferably electrically driven at both longitudinal ends in order to reduce amplitude variations of the excitation signal along the length of the electrode. This minimizes the effects of standing waves at high RF frequencies and provides a relatively even plasma intensity along the length of each electrode. Additionally, electrical contacts (not shown) may be provided to connect substrates 120a and 120b to the system ground, or to bias the substrates positive or negative with respect to the system ground, to control the plasma properties and the amount of electron/ion bombardment at the surface of the substrates. Magnetic fields may also be used to control plasma properties, i.e. confine the plasma and direct the movement of ions and electrons within the plasma.

With respect to materials, the rod electrodes 126 illustrated in FIGS. 2-4 may be formed from a variety of materials that are relatively high in thermal and electrical conductivity to achieve a uniform electrical field and uniform temperature along the length of the rod. Material that is inert in a nitrogen plasma or oxidizing environment, such as titanium or stainless steel, may be used.

Turning to size and shape, the rod electrodes 126 in one implementation that is suitable for commercial applications are cylindrical in shape, are about 1.2 cm in diameter and about 60 cm in length. The rod electrodes 126 are positioned parallel to one another about every 2 cm (i.e. 2 cm between the longitudinal axes of adjacent rod electrodes) in the direction of substrate travel and in the central plane CP of the deposition chamber interior. Thus, in the illustrated embodiment, the central plane CP is also the electrode plane. So configured and arranged, there will be forty eight of the rod electrodes 126 in a 100 cm long deposition chamber that has small electrode-free areas near the inlets and outlets.

The rod electrodes 126 are not, however, limited to these configurations and arrangements. For example, the rod electrodes may be other than circular in cross-sectional shape, as are the exemplary cylindrical rod electrodes 126. There may also be instances where the spacing between the rod electrodes 126 will vary, where some or all of the rod electrodes are slightly offset from the central plane CP and/or where some of the rod electrodes are not parallel to others. The cross-sectional size of the rod electrodes (e.g. the diameter where the rod electrodes are cylindrical) may also be varied from electrode to electrode to suit particular applications.

There are a number of advantages associated with the present electrode assembly 104. For example, the arrangement of the plurality of closely spaced rod electrodes 126 allows higher RF frequencies to be used to excite the plasma in the present PECVD system 100, as compared to the frequencies that can be used in conventional PECVD systems, when the systems are of commercial production size (i.e. where the substrates are relatively long and at least 0.5 m wide). The series of parallel rod electrodes 126, with alternating phases of applied RF power, forms a series of well characterized electronic transmission lines capable of supporting high frequency RF excitation in the range of 27-81 MHz. It has been shown in laboratory experiments that RF power in the 27-81 MHz excitation frequency range can provide higher deposition rates (i.e. about 5 nm/sec.) and better material quality than the conventional excitation frequency of 13.5 MHz. Conventional electrode designs are not conducive to these higher frequencies in commercial production sized systems because they create poorly controlled standing waves, which results in non-uniform plasma intensity and non-uniform deposition rates. Conversely, the present electrode assembly 104 produces well controlled standing waves and only minor variations in plasma intensity when excited to a frequency of 80 MHz over relatively long substrates that are at least 0.5 m wide.

Other advantages are associated with the creation of high intensity plasma regions 128 along the central plane CP (FIG. 3) of the deposition chamber 102 and low intensity plasma regions 130 near the substrates 120a and 120b. For example, the high intensity plasma regions 128 generate abundant atomic nitrogen, which is known to encourage the formation of silicon nitride with good barrier properties. Atomic nitrogen generated in the central plane CP will diffuse easily to the substrates and unlike experimental systems that have been reported in PECVD-related literature, does not have to flow through a tube or other apparatus through which much of the atomic nitrogen would react and be lost. The high intensity plasma regions 128 in the central plane CP between the rod electrodes 126 also generate intense UV photons that can easily flow to the substrates 120a and 120b. Unlike other experimental systems that have been reported in PECVD-related literature, the UV photons can flow to substrate without passing from outside the deposition chamber through a window or other apparatus. The presence of a window or similar component has the disadvantages of decreasing the photon intensity at the substrate and creating a significant maintenance issue when the window becomes degraded by color centers or other flaws formed or aggravated by UV absorption. The creation of low intensity plasma regions 130 near the substrates 120a and 120b reduces the electron/ion bombardment of the substrates and potential damage to the deposited silicon nitride by electrons and/or ions.

It should also be noted that a series of rod electrodes that are arranged in the manner described above does not create a uniform electric field and plasma in the substrate travel direction indicated by arrows A and, instead, will create an electric field and plasma that varies periodically in the travel direction from the area closet to a rod electrode to the midpoint between two rod electrodes. The deposition rate and barrier properties of the deposited material could, therefore, vary periodically in the travel direction. The illustrated embodiment eliminates this periodic variation in electric field and plasma intensity in a variety of ways. Periodic variations are reduced to a large extent by insuring that the distance between adjacent rod electrodes 126, as well as the distance between the rod electrodes and the substrates 120a and 120b, is within a diffusion length. For example, in the exemplary embodiments, the spacing between adjacent rod electrodes 126, is less than half of the distance from the central plane CP to the substrates. In fact, the spacing between adjacent rod electrodes 126 and from the rod electrodes to the substrates 120a and 120b should be minimized so that rapid diffusion can further reduce variations in the deposition rate. Finally, if necessary, the substrates 120a and 120b can be moved relatively rapidly in the non-uniform direction (i.e. the direction indicated by arrows A) to average out any small, remaining variations in the deposition rate.

The electrode assembly 104 may, in some implementations of the present inventions, also be used during the deposition process to deliver reactant materials to the deposition chamber 102 and to evacuate exhaust from the deposition chamber. To that end, and referring to FIGS. 3 and 4, the rod electrodes 126 include interior lumens 132 that are connected to the manifold 112a (or 112b) and the apertures 134 that connect the interior lumens to the interior of the deposition chamber 102. Each rod electrode 126 includes two sets of apertures 134, one set that faces the substrate 120a and another set that faces the substrate 120b. The interior lumens 126 in the illustrated embodiment are connected to the manifolds 112a and 112b such that, in the direction of substrate travel (i.e. the direction indicated by arrows A) the rod electrodes 126 alternate from one rod electrode to the next between delivering reactant materials and evacuating exhaust. The reactants are represented by arrows R in FIGS. 3 and 4, while the exhaust is represented by arrows E. More specifically, the manifold 112a connects the lumens 132 of the rod electrodes 126 that are delivering reactant material to the reactant gas source 110 and the manifold 112b connects the lumens of the rod electrodes that are evacuating exhaust to the exhaust device 114. The manifolds 112a and 112b are also connected to both longitudinal ends of each of the associated rod electrodes 126. As such, reactant materials enter both longitudinal ends of each of the rod electrodes 126 that are delivering reactant materials, and the exhaust exits both longitudinal ends of each of the rod electrodes that are evacuating exhaust.

The exemplary lumens 132 in the illustrated embodiment are slightly smaller than the rod electrodes 126. For example, the lumen 132 would be about 1.0 cm in diameter in a cylindrical rod electrode 126 that is itself 1.2 cm in diameter, and about 0.5 cm in diameter in a cylindrical rod electrode that is itself 0.6 cm in diameter. The apertures 134, which are about 350 μm in diameter in the larger rod electrodes 126 and about 200 μm in diameter in the smaller rod electrodes, are positioned about every 0.5 cm along the length of the rod electrodes 126. However, for both the rod electrodes 126 delivering reactant materials and the rod electrodes evacuating exhaust, there is preferably a slight variation in aperture spacing from the longitudinal ends of the rod electrodes 126 to the centers in order to compensate for the pressure drop that occurs between the longitudinal ends, which are connected to the manifold 112a, and the center. More specifically, for 0.6 cm diameter rod electrodes 126 with 200 um apertures 134, there is about 5% less spacing at the center (i.e. about 0.475 cm spacing) and about 5% more spacing at the longitudinal ends (i.e. about 0.525 cm spacing) and the change occurs linearly. This results in a uniform flow rate through the apertures 134 in the rod electrodes 126 from one longitudinal end of the rod electrodes 126 to the other. The apertures 134 may also be aligned with one another from one rod electrode 126 to the next, or staggered, as applications require.

As discussed above with reference to FIGS. 3 and 4, supplying energy in alternating phases from one rod electrode 126 to the next adjacent rod electrode (as represented by the “+” and “−” signs) creates high intensity plasma regions 128 and low intensity plasma regions 130. The apertures 134 are positioned so that they do not face the high intensity plasma regions 128 and, instead, face the low intensity plasma regions 130. In the exemplary implementation, the apertures 134 face in directions that are perpendicular to the central plane CP and are positioned on the portions of the rod electrodes 126 that are closest to the substrates 120a and 120b. The angle of the apertures 134 relative to the central plane CP may, however, be adjusted as applications require. For example, the angle may be up to forty-five (45) degrees from perpendicular. Because the reactant material, i.e. silane in the exemplary implementation, is introduced into the low intensity plasma regions 130, the silane rapidly diffuses and dilutes itself into the nitrogen atmosphere inside the chamber before encountering regions of intense plasma 128. This reduces the formation of higher order silanes and/or silicon particles within the plasma.

The reactant gas source 110 may be used to fill the deposition chamber 102 with ammonia or nitrogen, or a mixture of ammonia, nitrogen and argon (Ar), at the desired pressure (e.g. 50 mTorr) prior to the excitation of the rod electrodes 126 and the introduction of the silane or other reactant material. The rod electrodes 126 are then excited to initiate the plasma. During the actual deposition process, the reactant gas source 110 supplies pure or highly concentrated silane to the rod electrodes 126 that are supplying reactants by way of the manifold 112a. The apertures 134 direct the pure silane into the low intensity plasma regions 130 and the silane diffuses rapidly (i.e. within a few milliseconds) into the nitrogen (ammonia or mixture) already in the deposition chamber 102. The diffusion occurs before the silane reaches the high intensity plasma regions 128 where the silane is consumed by the decomposition into silicon and hydrogen (SiH₄→Si+2H₂). The rapid diffusion and dilution into the nitrogen atmosphere with the deposition chamber 102 prior to encountering high intensity plasma regions 128, as well as the relatively short rod electrode to adjacent rod electrode distance that the silane travels and correspondingly short residence time within the deposition chamber, also reduces the formation of higher order silanes (Si₂H₆, Si₃H₈, etc.) and/or silicon particles within the plasma. The silicon nitride is deposited onto the substrates 120a and 120b, while the hydrogen and a very small amount of unused silane is removed by the apertures 134 in the other rod electrodes 126 and the exhaust device 114. As an example, the overall reaction for silicon nitride deposition in the PECVD process using silane and ammonia can be written as follows:

3SiH₄+4NH₃=Si₃N₄+12H₂

In the embodiment detailed above, the flow of silane and the power are carefully controlled to set the deposition rates. Nitrogen from ammonia is abundant in the chamber and does not limit the deposition rates. In an alternate embodiment, both silane and ammonia can be introduced into the chamber through the apertures 134 in the rod electrodes. This arrangement could be used to control the ratio of NH₃ and silane to be close to 4:3 as in the chemical reaction shown above, if desired.

Under PECVD conditions, SiNₓH_{y} is obtained as the final product. Hydrogen containing SiNₓH_{y} is a good passivation layer for numerous applications. Hydrogen content depends upon several factors depending upon SiH₄ to NH₃ flow ratio, effective dissociation and utilization of SiH₄, and the substrate temperature. In general in PECVD process, the free radicals generated by the plasma environment activate the chemical reaction at lower temperatures than thermal chemical vapor deposition.

In the inventive process, high frequency leads to higher ionization which in turns leads to intensive dissociation of silane (SiH₄) and ammonia (NH₃). High ionization provides enough N atoms to consume all of the dissociated silane. High frequency will also allow the use of lower pressure thereby minimizing the particulate contaminants. High frequency reduces ion energy due to decrease in sheat voltage leading to a lower impact on the substrate by the ions.

The input flow rate of the pure silane needs to be only slightly greater than the rate at which the silane is consumed because only a small amount of the silane is wasted. More specifically, when the gas in the deposition chamber reaches the apertures 134 in the rod electrodes 126 that are being used to evacuate exhaust from the deposition chamber 102, the concentration of silane can be very small.

Additionally, because the deposition reaction is SiH₄+NH₃→SiNₓ+xH₂, the exhaust gas flow rate should be several times the input gas flow rate in order to maintain a constant pressure in the deposition chamber 102. All of the hydrogen generated in the deposition reaction is removed by the exhaust. Hence a high percentage of the silane is used in the deposition process. Conventional PECVD systems, on the other hand, convert only about 5-10% of the silane into silicon nitride and the remainder is wasted. Of course, in conventional PECVD systems and the present PECVD system 100, some of the silicon nitride is deposited onto the walls of the deposition chamber. This brings conventional PECVD systems down to about 5% utilization efficiency, i.e. about 5% of the silicon input as silane gas is actually deposited as silicon nitride onto substrates. As noted above, the geometry of the present deposition chamber 102 reduces the percentage of deposits onto the walls of the deposition chamber and, accordingly, the overall utilization efficiency of the present PECVD system 100 is about 50% and higher.

Another advantage associated with the supply of pure silane through some of the rod electrodes 126 and the evacuation of exhaust through others is that it facilitates much lower gas flow rates than conventional PECVD systems. The lower flow rates allow for a much lower capacity exhaust device 114 (e.g. vacuum pump) to be used to evacuate the reaction products from the deposition chamber 102 and maintain a constant chamber pressure. The very short travel distance from a rod electrode 126 that is supplying reactant to a rod electrode that is evacuating exhaust (e.g. substantially less than one-twentieth ( 1/20) of the length and/or height of the deposition chamber 102 in the illustrated embodiment) ensures that the dwell time for silane in the reaction chamber 102 is short even though the flow rates are low. The short dwell time minimizes the formation of high order silanes and/or silicon particles.

As noted above, in an alternative implementation, the rod electrodes 126 are driven in phase with each other, and the substrates 120a and 120b held at ground potential (or at ground with a small DC bias), to create a relatively uniform electric field and plasma in each of the two areas between the central plane CP and the substrates. Here, the rod electrodes 126 may be rotated ninety (90) degrees from the orientation illustrated in FIG. 3 so that the apertures 134 are facing adjacent rod electrodes and reactant is supplied to, and exhaust is evacuated from, the region where the electrical field is minimized. This implementation of the inventions also benefits from the very short travel distance from a rod electrode 126 that is supplying reactant to a rod electrode that is evacuating exhaust in that the dwell time for silane in the reaction chamber 102 is short, even though the flow rates are low, and the short dwell time minimizes the formation of high order silanes and/or silicon particles.

The reactant gas source 110, which may be used to supply the deposition chamber 102 with silane and ammonia during the deposition process, includes a plurality of storage containers G₁-G_{N}. Other gasses that may be stored include argon, nitrogen, hydrogen, oxygen, methane, acetylene. The gasses may be stored under pressure and, to that end, the reactant gas source 110 includes a plurality of valves 136 that control the flow rate of the gasses from the storage containers G₁-G_{N}. It should also be noted that the present inventions are not limited to gaseous reactant material. Sources of liquid and/or solid reactants may also be provided if required by particular processes. The ammonia generates atomic nitrogen and atomic hydrogen, the nitrogen generates atomic nitrogen, the oxygen generates atomic oxygen, and the methane and acetylene generate carbon radicals and atomic hydrogen with application of high frequency RF power.

The controller 116 may be used to control a variety of aspects of the deposition process. For example, the rate at which pure silane is supplied to the deposition chamber 102 and the rate at which exhaust is evacuated from the deposition chamber may be controlled based upon data from the sensors 118. As noted above, the silane input rate should be slightly greater than the rate at which the silane is consumed (i.e. the deposition rate) because only a small amount of the silane is wasted. Thus, for a particular deposition rate and power level applied to the rod electrodes 126 by the power supply 108 (or “plasma power”), the input flow rate may be adjusted by feedback from the sensors 118 to achieve the desired concentration of silane in the exhaust gas. For an operating point in which the deposition rate is limited by the plasma power, the exhaust gas concentration of silane will typically be about 5%. Alternatively, for operating points in which the deposition rate is limited by silane depletion, the input flow rate of the silane is adjusted to be equal to the rate consumed in the deposition and the concentration of silane in the exhaust gas approaches zero. The exhaust rate is also controlled by feedback to maintain the pressure in the deposition chamber 102 at the desired pressure (e.g. about 10-1000 mTorr, preferably about 50 mTorr). The temperature of the substrates 120a and 120b and the frequency and power level of the plasma excitation will also typically be controlled to achieve the desired quality of silicon at the desired deposition rate. Accordingly, the sensors 118 may include a gas concentration sensor associated with the exhaust device 114, a pressure sensor within the deposition chamber 102, and a temperature sensor associated with the substrates 120a and 120b. A sensor that detects the presence of a plasma to verify correct operation may also be provided.

Controlling the PECVD process in the manner described above allows the present PECVD system to perform continuous deposition processes at a stable, steady state with stable temperature, gas flow, gas concentrations, deposition rates, etc. The controller 116 can use feedback from the sensors 118 to adjust the parameters of the stable, steady state and achieve the desired material properties. The combination of steady state operation and parameter adjustment, based on sensors within the system as the deposition process proceeds, together with rapid diffusion to reduce any non-uniformity allows the manufacture of the present system to be much less precise in mechanical tolerances, and less uniform in gas flow. As a result, the present system can be manufactured much less expensively than conventional “batch mode” systems which deposit material with comparable uniformity and semiconducting properties.

FIG. 5 illustrates an exemplary solar cell with a barrier coating deposited according to the inventive method. Substrate 138 is a solar cell made by depositing a functional film stack 140 on an underlying material 142. Barrier coating 144 comprises passivation layers 144a and 144b, which may be of identical or different compositions. Those skilled in the art will recognize that a variety of other coatings, deposited on a variety of other coated or uncoated substrates, are within the scope of the invention if the deposition is performed according to the inventive method.

The present PECVD system 100 may be used to produce a variety of material layers. Although the inventions are described in the context of the formation of thin films of silicon nitride (SiNx) from silane (SiH₄) and ammonia (NH₃), they are not limited to any particular types of films or input reactant material. By way of example, but not limitation, the PECVD system 100 may be used to form silicon nitride, silicon oxide, silicon carbide, titanium carbide, and other layers on large substrates (e.g. 1 m×0.5 m) that may be utilized in silicon thin film photovoltaic cells and other large area, low cost thin-film devices. While barrier coatings for silicon based thin film devices have been described, it is to be appreciated that substantial benefit may be achieving by using this method to deposit barrier coatings on window glass, flat panel displays, lenses, etc and other large area substrates that would benefit from a thin-film barrier coating. Similarly, while deposition of barrier coatings on large area substrates has been described and is particularly advantageous, it is to be appreciated that the inventive method may also be used to deposit barrier coatings on small area substrates.

From the foregoing, it is to be appreciated that the inventive PECVD process for depositing barrier coating layers on substrates has a number of advantages as compared to conventional PECVD process. These advantages include a high deposition rate (5 nm/sec), low substrate temperature (less than about 150 degrees Celsius, preferably about 100° C.), less particulate formation, effective silane (SiH₄) utilization due to close proximity of the precursor injection, and substantially uniform deposition due to the multitubular injection manifold design. The process is particularly advantageous for depositing a barrier coating on large area substrates (1 m×0.5 m and larger)

Although particular embodiments of the invention have been described in detail for purposes of illustration, various modifications may be made without departing from the spirit and scope of the invention. Accordingly, the invention is not to be limited, except as by the appended claims.

1. A method of forming a barrier coating on one or more thin film devices disposed in a deposition chamber, said method comprising:
delivering a reactant material into the deposition chamber; and
forming a plasma from the reactant material by applying high frequency RF power to an electrode assembly in the deposition chamber to deposit said barrier coating on the one or more thin film devices, wherein (i) a temperature at which the barrier coating is deposited is less than about 150° C. (ii) the high frequency RF power is between 27 to 81 MHz and (iii) the pressure within the deposition chamber is maintained at about 10-1000 mTorr.

2. The method of claim 1, wherein the one or more thin film devices are silicon based thin film devices comprising one of individual sheets or a continuous web selected from the group consisting of glass, polyimide and stainless steel deposited with amorphous, crystalline or partially crystalline silicon P-I-N along with metal conductor layers.

3. The method of claim 2, wherein the one or more silicon based thin film devices are about 1 m×0.5 m and larger.

4. The method of claim 1, wherein the barrier coating is selected from the group consisting of nitrides, oxides and carbides.

5. The method of claim 4, wherein the reactant material comprises a reactant gas comprising silane and at least one of ammonia, nitrogen, argon, oxygen, methane and acetylene.

6. The method of claim 5, wherein the barrier coating is selected from the group consisting of silicon nitride, silicon oxide, and silicon carbide coating.

7. The method of claim 4, wherein the barrier coating is titanium carbide coating.

8. The method of claim 5, wherein the reactant gas is silane and ammonia and the application of high frequency RF power creates low intensity plasma regions near the one or more thin film devices and high intensity plasma regions along the central plane of the deposition chamber which generate atomic nitrogen which diffuses within the deposition chamber to the one or more thin film devices.

9. The method of claim 8, wherein the electrode assembly comprises a plurality of rod electrodes that deliver the silane into the low intensity plasma regions.

10. The method of claim 9, wherein the silane input rate is greater than the deposition rate.

11. The method of claim 2, wherein the electrode assembly and the one or more silicon based thin film devices are closely spaced within the deposition chamber.

12. The method of claim 11, wherein the electrode assembly comprises a plurality of rod electrodes and the distance between adjacent rod electrodes and between the rod electrodes and the one or more silicon based thin film devices is within a diffusion length.

13. The method of claim 9, wherein one or more of the rod electrodes further evacuate exhaust from the deposition chamber, the travel distance from the one or more rod electrodes delivering silane to the one or more rod electrodes evacuating exhaust is closely spaced to substantially minimize silane dwell time within the deposition chamber.

14. The method of claim 13, wherein the exhaust flow rate from the deposition chamber equals or exceeds the input gas flow rate.

15. A method of forming and depositing a barrier coating over one or more thin film devices disposed in a deposition chamber, said method comprising:
delivering a reactant gas comprising silane and at least one of ammonia, nitrogen, argon, methane, oxygen, and acetylene into the deposition chamber;
forming a plasma from the reactant gas by applying high frequency RF power between 27-81 MHz to an electrode assembly in the deposition chamber to deposit said barrier coating over the one or more thin film devices and wherein said thin film devices are maintained at a temperature of about 100° C. during deposition of said barrier coating, and the pressure within the deposition chamber is maintained at about 10-1000 mTorr.

16. The method of claim 15, wherein the barrier coating is selected from the group consisting of silicon nitride, silicon oxide, and silicon carbide coatings.

17. The method of claim 16, wherein the reactant gas is silane and one of ammonia, nitrogen, oxygen, methane and acetylene and the application of high frequency RF power creates low intensity plasma regions near the one or more thin film devices and high intensity plasma regions along the central plane of the deposition chamber which respectively generate atomic nitrogen and atomic hydrogen, atomic nitrogen, atomic oxygen, carbon radicals and atomic hydrogen, and carbon radicals and atomic hydrogen which diffuse within the deposition chamber to the one or more thin film devices and wherein the electrode assembly comprises a plurality of rod electrodes either delivering silane and one of ammonia, nitrogen, oxygen, methane and acetylene into the low intensity plasma regions or evacuating exhaust from the deposition chamber, the travel distance from the plurality of electrodes delivering silane to the plurality of electrodes evacuating exhaust is closely spaced to substantially minimize silane dwell time within the deposition chamber.

18. The method of claim 17, wherein the distance between adjacent rod electrodes and between the rod electrodes and the one or more thin film devices is within a diffusion length.

19. The method of claim 18, wherein the delivery of silane and the application of high frequency RF power are controlled to set a deposition rate.
